(19) United States
(12) Patent Application Publication
(10) Pub. No.: US 2026/0038775 A1
(43) Pub. Date: Feb. 5, 2026

(54) SUBSTRATE PROCESSING APPARATUS AND SUBSTRATE PROCESSING METHOD

(71) Applicant: SEMES CO., LTD., Cheonan-si (KR)

(72) Inventors: Young Bae YUN, Cheonan-si (KR); Eui Keun PARK, Cheonan-si (KR)

(73) Assignee: SEMES CO., LTD., Cheonan-si (KR)

(21) Appl. No.: 19/203,612

(22) Filed: May 9, 2025

(30) Foreign Application Priority Data
Aug. 5, 2024 (KR) 10-2024-0104175

(51) Int. Cl. H01J 37/32

(52) U.S. Cl. CPC H01J 37/32642; H01J 37/32449; H01J 2237/334; H01J 2237/335

(57) ABSTRACT

Proposed are a substrate processing apparatus and a substrate processing method capable of effectively removing foreign substances formed on the lower surface of a focus ring that can be raised. The substrate processing apparatus that performs a processing process using plasma includes a process chamber configured to form a processing space for a substrate, a chuck plate configured to support the substrate, a focus ring provided on an upper edge of the chuck plate, a lifting pin configured to lift the focus ring, a gas supply part configured to supply process gas to the processing space, a high-frequency power source configured to provide high-frequency power to generate plasma in the processing space, and a controller, wherein the controller is set to execute steps of establishing an atmosphere inside the process chamber, and performing plasma treatment on the substrate.

### CROSS REFERENCE TO RELATED APPLICATION

The present application claims priority to Korean Patent Application No. 10-2024-0104175, filed Aug. 5, 2024, the entire contents of which are incorporated herein for all purposes by this reference.

### BACKGROUND

### 1. Field

The present disclosure relates to a substrate processing apparatus using plasma and a substrate processing method performed by the substrate processing apparatus.

### 2. Description of the Related Art

Semiconductor (or display) manufacturing is a process of manufacturing semiconductor devices on a substrate (e.g., wafer), and includes, for example, exposure, deposition, etching, ion implantation, cleaning, etc. In order to perform each manufacturing process, semiconductor manufacturing equipment for performing individual processes is provided in cleanrooms of a semiconductor manufacturing plant so that a process is performed on a substrate put into the semiconductor manufacturing equipment.

Plasma is used in etching or deposition to treat substrates. For plasma processing, a process gas is supplied to a process chamber where a substrate is located, and high-frequency power is supplied to generate plasma, and the energy of the plasma reacts with a specific material on the substrate. It is important that plasma energy be delivered uniformly over the entire area of the substrate, and because plasma exhibits weak characteristics at the edge area of the substrate, structures are placed around the edge area of the substrate to control the plasma.

A ring called a focus ring (or edge ring) is positioned at the edge of the substrate as a configuration for controlling plasma at the edge area of the substrate. Since the focus ring can be etched by plasma as the plasma processing is repeated, a lifting mechanism is applied for adjusting the height of the focus ring.

The surface of a focus ring that is initially manufactured is not smooth and has the characteristics of being sharp or rough. In particular, foreign substances may be attached to the sharp portion formed on the lower surface of the focus ring that is raised by the lifting mechanism. Foreign substances attached to the lower surface of the focus ring are not easily removed and continuously accumulate, which adversely affects the performance of substrate processing.

### SUMMARY

Accordingly, the present disclosure has been made keeping in mind the above problems occurring in the related art, and an objective of the present disclosure is to provide a substrate processing apparatus and a substrate processing method capable of effectively removing foreign substances formed on the lower surface of a focus ring that can be raised.

A substrate processing apparatus that performs a processing process using plasma according to the present disclosure includes: a process chamber configured to form a processing space for a substrate; a chuck plate configured to support the substrate; a focus ring provided on an upper edge of the chuck plate; a lifting pin configured to lift the focus ring; a gas supply part configured to supply process gas to the processing space; a high-frequency power source configured to provide high-frequency power to generate plasma in the processing space; and a controller, wherein the controller may be set to execute steps of: establishing an atmosphere inside the process chamber; and performing plasma treatment on the substrate, wherein the step of establishing the atmosphere inside the process chamber may include steps of: lifting the focus ring; supplying a first process gas to the processing space while the focus ring is lifted, and modifying a surface of the focus ring using plasma generated from the first process gas; supplying a second process gas while the focus ring is lifted and removing foreign substances remaining on the surface of the focus ring using plasma generated from the second process gas; and lowering the focus ring.

In an embodiment of the present disclosure, in the step of modifying the surface of the focus ring, a sharp portion formed on the surface of the focus ring may be smoothed.

In an embodiment of the present disclosure, the first process gas may include at least one of nitrogen trifluoride (NF₃), trifluoromethane (CHF₃), carbon tetrafluoride (CF₄), and nitrogen (N₂).

In an embodiment of the present disclosure, the step of modifying the surface of the focus ring may be performed while an unprocessed substrate is seated on the chuck plate.

In an embodiment of the present disclosure, the step of removing foreign substances remaining on the surface of the focus ring may be performed with the unprocessed substrate removed.

In an embodiment of the present disclosure, the second process gas may include at least one of tetrafluoride (CF₄), oxygen (O₂), helium (He), and argon (Ar).

A substrate processing method performed in a substrate processing apparatus that performs a processing process using plasma according to the present disclosure includes steps of: establishing an atmosphere inside a process chamber forming a processing space for a substrate; and performing plasma treatment on the substrate, wherein the step of establishing the atmosphere inside the process chamber may include steps of: lifting the focus ring located on an upper edge of a chuck plate supporting the substrate; supplying a first process gas to the processing space while the focus ring is lifted, and modifying a surface of the focus ring using plasma generated from the first process gas; supplying a second process gas while the focus ring is lifted and removing foreign substances remaining on the surface of the focus ring using plasma generated from the second process gas; and lowering the focus ring.

A substrate processing apparatus that performs a processing process using plasma according to the present disclosure includes: a process chamber configured to form a processing space for a substrate; a chuck plate configured to support the substrate; an insulation pillar located at an edge of the chuck plate and configured to have a pin hole formed therein; a support ring configured to surround a side of the chuck plate on the insulation pillar; a focus ring configured to cover at least a portion of an upper portion of the support ring; a lifting pin configured to be movable in a vertical direction in the pin hole of the insulation pillar, and to vertically overlap with at least a portion of the support ring and at least a portion of the focus ring; a gas supply part configured to supply process gas to the processing space; a high-frequency power source configured to provide high-frequency power to generate plasma in the processing space; and a controller.

According to the present disclosure, in the step of establishing an atmosphere inside a process chamber, by modifying the lower surface of a focus ring to be smooth with a first process gas while the focus ring is lifted, foreign substances remaining on the lower surface of the focus ring can be effectively removed by means of a second process gas, and foreign substances can be prevented from attaching to the lower surface of the focus ring.

### BRIEF DESCRIPTION OF THE DRAWINGS

FIG. 1 shows the structure of a substrate processing apparatus according to the present disclosure.

FIG. 2 shows the structure of an electrostatic chuck in the substrate processing apparatus according to the present disclosure.

FIGS. 3 to 5 are views showing a structure for lifting a focus ring and a support ring in the substrate processing apparatus according to the present disclosure.

FIG. 6 is a flowchart showing a substrate processing method performed by the substrate processing apparatus according to the present disclosure.

FIG. 7 is a flowchart showing an example of the steps for establishing an atmosphere inside a process chamber.

FIG. 8 shows a process of modifying the lower surface of the focus ring using a first process gas.

FIG. 9 shows a process of removing foreign substances remaining on the lower surface of the focus ring using a second process gas.

### DETAILED DESCRIPTION OF EXEMPLARY EMBODIMENTS

Hereinafter, with reference to the accompanying drawings, embodiments of the present disclosure will be described in detail so that those skilled in the art may easily carry out the present disclosure. The present disclosure may be embodied in many different forms and is not limited to the embodiments set forth herein.

In order to clearly describe the present disclosure, parts irrelevant to the description are omitted, and the same reference numerals are assigned to the same or similar components throughout the specification.

In addition, in various embodiments, components having the same configuration will be described only in representative embodiments by using the same reference numerals, and in other embodiments, only configurations different from the representative embodiments will be described.

Throughout the specification, when a part is said to be “connected (or coupled)” to another part, this includes not only the case of being “directly connected (or coupled)” but also “indirectly connected (or coupled)” with another member in between. In addition, when a part “includes”, “has”, or “comprises” a certain part, this means that other components may be further included without excluding other components unless otherwise stated.

Unless otherwise defined, all terms used herein, including technical or scientific terms, have the same meaning as commonly understood by a person skilled in the art. Terms such as those defined in the commonly used dictionaries should be construed as having meanings consistent with the meanings in the context of the related art and shall not be construed in ideal or excessively formal meanings unless expressly defined in this application.

As semiconductor manufacturing equipment, a substrate processing apparatus of the present embodiment can be used to perform a process on a substrate such as a semiconductor wafer or a flat panel display panel. In particular, a substrate processing apparatus 1 of the present embodiment is a device that performs etching or deposition on a substrate by using plasma.

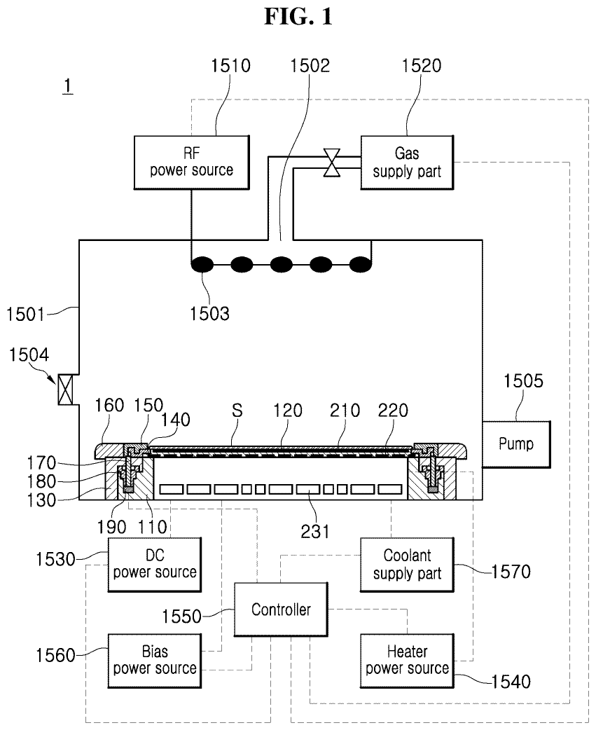

FIG. 1 shows the structure of the substrate processing apparatus 1 according to the present disclosure. Referring to FIG. 1, the substrate processing apparatus 1 may include an electrostatic chuck 10, a process chamber 1501, a gas supply pipe 1502, an upper electrode 1503, a door 1504, a pump 1505, a radio frequency (RF) power source 1510, a gas supply part 1520, and a controller 1550.

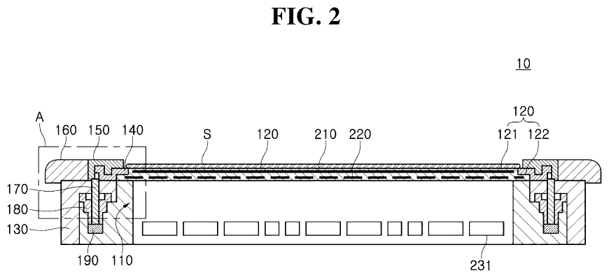

In an embodiment, the electrostatic chuck 10 of the substrate processing apparatus 1 may be a device that fixes a substrate S by electrostatic force. The detailed structure of the electrostatic chuck 10 will be described with reference to FIGS. 2 to 5. The electrostatic chuck 10 may include a base plate 110, a chuck plate 120, an insulation pillar 130, a support ring 140, a focus ring 150, a fixing ring 160, a lifting pin 170, a guide holder 180, and a ring lifting power source 190. An electrostatic electrode 210 and a heater 220 are inserted into the chuck plate 120, and a coolant passage 231 is formed in the base plate.

In an embodiment, the base plate 110 may be a cylindrical pedestal. The base plate 110 may be made of a metal material (e.g., aluminum).

In an embodiment, the chuck plate 120 may be on the base plate 110. The chuck plate 120 may be a plate on which the substrate S is mounted. The chuck plate 120 may include a non-conductive material (e.g., ceramic) that is less deformed by heat for resistance to high-temperature plasma.

The chuck plate 120 may include a first part 121 on which the substrate S is mounted, and a second part 122 extending outwardly from below the first part 121. When the chuck plate 120 is viewed from above, the upper surface of the first part 121 and a portion of the upper surface of the second part 122 may be exposed.

In an embodiment, the insulation pillar 130 may be on the outside of the chuck plate 120. More specifically, the insulation pillar 130 may surround the base plate 110 on the outside of the chuck plate 120. Additionally, the insulation pillar 130 may be a pillar including an insulating material.

A pin hole H1 may be formed in the insulation pillar 130. The pin hole H1 may provide a space in which the lifting pin 170 to be described later may move in the vertical direction. The pin hole H1 may overlap with at least a portion of the support ring 140 and at least a portion of the focus ring 150 in the vertical direction.

In an embodiment, the support ring 140 may be a ring that wraps around the side of the chuck plate 120 on the insulation pillar 130. More specifically, the support ring 140 may wrap around the side of the first part 121 and the upper surface of the second part 122 of the chuck plate 120 on the insulation pillar 130. Since the support ring 140 wraps around the side of the chuck plate 120, the risk of damage to the chuck plate 120 by plasma during the substrate processing process may be reduced. In addition, when the substrate S is placed on the chuck plate 120, a portion of the support ring 140 may overlap a portion of the edge of the substrate S in the vertical direction.

The support ring 140 may be a ring that is moved vertically by the lifting pin 170. More specifically, the lifting pin 170 may be located below the support ring 140, and at least a portion of the support ring 140 may overlap a portion of the lifting pin 170 in the vertical direction. The support ring 140 may be driven vertically by an external force that the lifting pin 170 transmits to the support ring 140.

The support ring 140 may be driven vertically while the substrate S is not seated on the chuck plate 120. Since the support ring 140 can be driven vertically by the lifting pin 170, the support ring 140 may be replaced with a new ring without opening the chamber by a separate transport device. Accordingly, when the support ring 140 is replaced, the change in the environment within the process chamber 1501 may be small, so that the yield of the substrate processing process may be improved.

In an embodiment, the focus ring 150 may be a ring that covers a portion of the upper part of the support ring 140. The focus ring 150 may prevent etching of the support ring 140 by plasma during the substrate processing process.

The focus ring 150 may be a ring that affects the shape of plasma generated in the substrate processing process. For example, when the shape of the focus ring 150 or the vertical separation distance between the focus ring 150 and the insulation pillar 130 changes, the shape of plasma generated in the substrate processing process may also change. The focus ring 150 may be a ring that includes a material such as quartz, silicon carbide, silicon oxide, aluminum oxide, etc.

The focus ring 150 may be a ring that is moved vertically by the lifting pin 170. More specifically, the lifting pin 170 may be located below the focus ring 150, and at least a portion of the focus ring 150 may overlap a portion of the lifting pin 170 in the vertical direction. The focus ring 150 may be driven vertically by an external force that the lifting pin 170 transmits to the focus ring 150.

The focus ring 150 may be moved vertically while the substrate S is seated on the chuck plate 120. The focus ring 150 may be moved vertically in a process in which the substrate S is processed. The vertical separation distance between the focus ring 150 and the insulation pillar 130 may be controlled by the lifting pin 170. Accordingly, the shape of the plasma generated in the substrate processing process may also be controlled by the lifting pin 170. For example, if a portion of the focus ring 150 is etched due to repetition of the substrate processing process and the shape of the plasma is different from the previously predicted shape, the focus ring 150 may be driven vertically by the lifting pin 170. Accordingly, the plasma may be formed into the previously predicted shape in the substrate processing process.

Since the focus ring 150 may be driven vertically by the lifting pin 170, the focus ring 150 may be replaced with a new ring without opening the chamber by a separate transport device. Accordingly, when replacing the focus ring 150, the change in the environment within the chamber may be small, so that the yield of the substrate processing process may be improved.

In an embodiment, the fixing ring 160 may be a ring that covers a portion of the upper surface of the insulation pillar 130 to surround the support ring 140 and the focus ring 15). The fixing ring 160 may be located outside the pin hole H1 of the insulation pillar 130 and may not overlap with the lifting pin 170 in the vertical direction. Accordingly, the fixing ring 160 may not interfere with the vertical movement of the lifting pin 170.

In an embodiment, the lifting pin 170 may be a pin that moves vertically in the pin hole H1 of the insulation pillar 130. More specifically, the lifting pin 170 may move vertically within the pin hole H1 to drive the support ring 140 and the focus ring 150 in the vertical direction.

The lifting pin 170 may include a rod-shaped pin extending vertically within the pin hole H1. The lifting pin 170 may be provided in plural numbers, and the plurality of lifting pins 170 may be provided symmetrically with respect to the center of the chuck plate 120. For example, the lifting pin 170 may be three, and the three lifting pins 170 may be formed symmetrically with respect to the center of the chuck plate 120.

The lifting pin 170 may overlap at least a portion of the support ring 140 and at least a portion of the focus ring 150 in the vertical direction. Accordingly, the lift pin 170 may drive the support ring 140 and the focus ring 150 in the vertical direction.

The lifting pin 170 may be in any one of a first state, a second state, and a third state. The first state of the lifting pin 170 may be a state in which the lifting pin 170 does not drive the support ring 140 and the focus ring 150 in the vertical direction.

The second state of the lifting pin 170 may be a state in which the lifting pin 170 moves to drive the focus ring 150 in the vertical direction. As described above, the lifting pin 170 may drive the focus ring 150 in the vertical direction to change the shape of plasma generated in a substrate processing process. When the lifting pin 170 is in the second state, the focus ring 150 may be driven in the vertical direction to be vertically separated from the insulation pillar 130. When the lifting pin 170 is in the second state, the lifting pin 170 may not drive the support ring 140 in the vertical direction.

The third state of the lifting pin 170 may be a state in which the lifting pin 170 moves to vertically drive the support ring 140 and the focus ring 150 together. As described above, the lifting pin 170 may vertically drive the support ring 140 and the focus ring 150 for replacement of at least one ring among the support ring 140 and the focus ring 150. When the lifting pin 170 is in the third state, the support ring 140 and the focus ring 150 may be vertically driven together to be separated from the insulation pillar 130.

In an embodiment, the electrostatic chuck 10 of the present disclosure may include three or more rings, not limited to the case shown in FIG. 2. In addition, the plurality of rings may overlap at least a portion of the lifting pin 170 in the vertical direction. Accordingly, when the lifting pin 170 moves in the vertical direction, at least one ring among the plurality of rings may be driven in the vertical direction.

In an embodiment, the guide holder 180 may be a device configured to guide the movement of the lifting pin 170 in the vertical direction. The guide holder 180 may have a guide hole in which the lifting pin 170 is positioned. The guide holder 180 may prevent the tilting of the lifting pin 170, and accordingly, the lifting pin 170 may move in the vertical direction without tilting.

In an embodiment, the ring lifting power source 190 may be a device that delivers power to the lifting pin 170. More specifically, the ring lifting power source 190 may be a device that delivers power to the lifting pin 170 for vertical movement of the lifting pin 170. For example, the ring lifting power source 190 may include a hydraulic device, a motor, etc.

In an embodiment, the electrostatic electrode 210 generates an electrostatic force on the chuck plate 120. The electrostatic electrode 210 may be electrically connected to a direct current (DC) power source 1530. The electrostatic force may be generated between the electrostatic electrode 210 and the substrate S by a DC voltage applied from the DC power source 1530. The substrate S may be firmly placed on the chuck plate 120 by the electrostatic force.

In an embodiment, the heater 220 is configured to emit heat to heat the substrate S on the chuck plate 120. The heater 220 may be electrically connected to a heater power source 1540 to be described later. The heater 220 may include a plurality of heating elements. For example, the heater 220 may include at least one of a thermoelectric element, a resistance heater, and an inductance heater. The plurality of heating elements may be individually controlled for local temperature control of the substrate S on the chuck plate 120.

In an embodiment, the coolant passage 231 is formed inside the base plate 110 and is a path through which a coolant can flow. The coolant passage 231 is provided to cool a substrate on the chuck plate 120 or a plurality of electronic devices included in the electrostatic chuck 10. The coolant passage 231 is connected to a coolant supply part 1570 and forms a space through which the coolant provided from the coolant supply part 1570 flows. The coolant passage 231 forms a path through which at least one coolant among water, ethylene glycol, and silicone oil flows.

In an embodiment, the process chamber 1501 may provide an internal space, i.e., a processing space, for processing a substrate S. The electrostatic chuck 10 may be positioned in the processing space of the process chamber 1501. The gas supply pipe 1502 may be connected to the gas supply part 1520. The gas supply pipe 1502 may be configured to inject a process gas provided by the gas supply part 1520 into the interior of the process chamber 1501. The process gas may include an etching gas for etching the substrate S. The process gas may also include a protective gas for protecting patterns formed on the substrate S.

In an embodiment, the door 1504 may provide a path through which the substrate S can move. For example, the substrate S may be moved out of the process chamber 1501 through the door 1504 and may also be moved into the process chamber 1501 through the door 1504. The pump 1505 may be configured to control the internal pressure of the process chamber 1501. For example, the pump 1505 may increase the pressure by injecting air into the interior of the process chamber 1501. In addition, the pump 1505 may decrease the pressure by discharging air inside the process chamber 1501.

In an embodiment, the RF power source 1510 may be electrically connected to the upper electrode 1503. The RF power source 1510 may output high-frequency power suitable for generating plasma and transmit the output RF power to the upper electrode 1503. The RF power of the RF power source 1510 may be controlled by the controller 1550.

The DC power source 1530 may be electrically connected to the electrostatic electrode 210 of the electrostatic chuck 10. An electrostatic force may be generated between the electrostatic electrode 210 and the substrate S by the power applied from the DC power source 1530, for example, a DC voltage. The substrate S may be firmly placed on the chuck plate 120 of the electrostatic chuck 10 due to the electrostatic force.

In an embodiment, the heater power source 1540 may be electrically connected to the heater 220 of the electrostatic chuck 10. The heater power source 1540 may be connected to the controller 1550, and the heat generation amount of the plurality of heating elements included in the heater 220 may be controlled.

In an embodiment, a bias power source 1560 may be connected to the base plate 110. The bias power source 1560 may apply RF power to the base plate 110. The base plate 110 may serve as an electrode for generating plasma.

In an embodiment, the coolant supply part 1570 may be connected to the coolant passage 231 is formed in the base plate 230 and to the controller 1550. The coolant supply part 1570 may may control the flow rate and temperature of the coolant flowing in the coolant passage 231.

In an embodiment, the controller 1550 may be configured to control at least one among the RF power source 1510, the gas supply part 1520, the DC power source 1530, the heater power source 1540, the bias power source 1560, and the coolant supply part 1570.

In an embodiment, the controller 1550 may be configured to control the ring lifting power source 190 of the electrostatic chuck 10. The ring lifting power source 190 may be controlled by the controller 1550 to drive the support ring 140 and the focus ring 150.

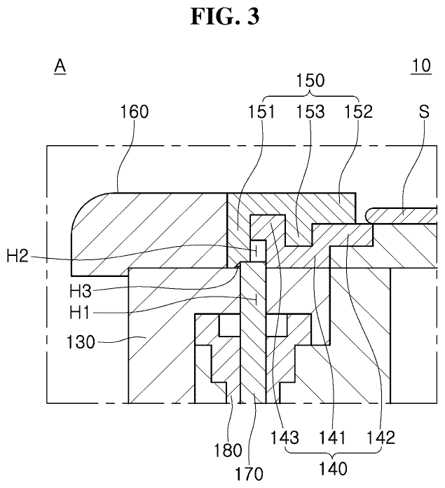

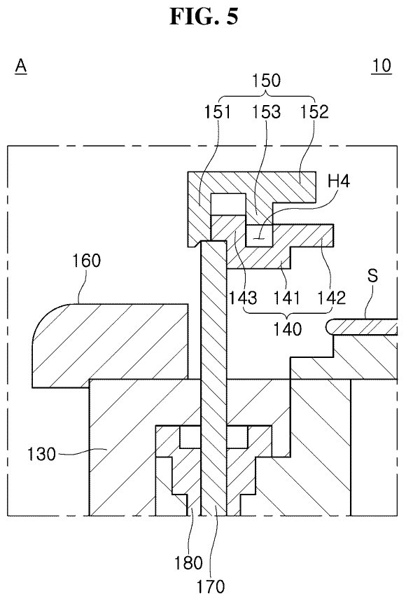

FIGS. 3 to 5 are enlarged cross-sectional views of a side A of the electrostatic chuck 10 according to an embodiment of the present disclosure. More specifically, FIG. 5 is an enlarged cross-sectional view of the side A of the electrostatic chuck 10 in the first state. The first state of the electrostatic chuck 10 may be a state in which the lifting pin 170 does not operate. In other words, the first state of the electrostatic chuck 10 may be a state in which the support ring 140 and the focus ring 150 do not operate in the vertical direction.

Referring to FIG. 3, the support ring 140 may include a support part 141, a protective part 142, and a first contact part 143. In an embodiment, the support part 141 may be a part of the support ring 140 that is mounted on the insulation pillar 130. In the first state of the electrostatic chuck 10, the support part 141 may come into contact with the insulation pillar 130.

In an embodiment, the protective part 142 may be a portion of the support ring 140 that extends horizontally from the inside of the support part 141 and wraps around the side of the chuck plate 120. More specifically, the protective part 142 may extend horizontally from the inside of the support part 141 and wrap around the side of the first part 121 and the upper surface of the second part 122 of the chuck plate 120. In the first state of the electrostatic chuck 10, the protective part 142 may come into contact with the side of the chuck plate 120.

In an embodiment, the first contact part 143 may be a portion of the support ring 140 extending vertically from the outside of the support part 141. A first driving groove H2 may be formed in the first contact part 143, and the first driving groove H2 may provide a space in which the aforementioned lifting pin 170 is positioned and may move vertically. The first driving groove H2 may overlap a portion of the lifting pin 170 in the vertical direction. In the first state of the electrostatic chuck 10, the first contact part 143 may not come into contact with the lifting pin 170.

In an embodiment, a protrusion groove H4 may be formed in the support ring 140. The protrusion groove H4 may be formed between the protective part 142 and the first contact part 143 of the support ring 140. The protrusion groove H4 of the support ring 140 may provide a space where a protrusion part 153 of the focus ring 150 is positioned.

The focus ring 150 may include a second contact part 151, a cover part 152, and the protrusion part 153. In an embodiment, the second contact part 151 may be a portion of the focus ring 150 that surrounds a side of the support ring 140 on the insulation pillar 130. In the first state of the electrostatic chuck 10, the second contact part 151 may be in contact with the insulation pillar 130. The protrusion part 153 may be a portion of the focus ring 150 that protrudes downward from the cover part 152. The protrusion part 153 may be accommodated in the protrusion groove H4 of the support ring 140.

A second driving groove H3 may be formed in the second contact part 151, and the second driving groove H3 may provide a space in which the aforementioned lifting pin 170 is positioned and may move in the vertical direction. The second driving groove H3 may overlap a portion of the lifting pin 170 in the vertical direction. In addition, the depth of the second driving groove H3 of the second contact part 151 may be smaller than the depth of the first driving groove H2 of the first contact part 143.

In an embodiment, the cover part 152 may be a portion of the focus ring 150, which extends horizontally from the second contact part 151 and covers a portion of the upper portion of the support ring 140. More specifically, the cover part 152 may extend horizontally from the upper portion of the second contact part 151 and cover a portion of the first contact part 143 and the protective part 142 of the support ring 140.

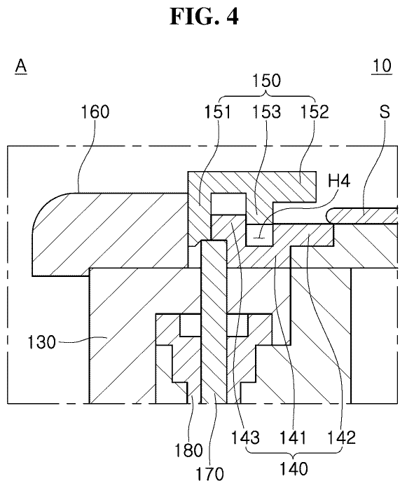

FIG. 4 is an enlarged cross-sectional view of the side A of the electrostatic chuck 10 in the second state. The second state of the electrostatic chuck 10 may be a state in which the lifting pin 170 drives the focus ring 150 in the vertical direction. In the second state of the electrostatic chuck 10, the surface treatment and foreign substance removal of the focus ring 150 described below may be performed.

Referring to FIG. 4, when the electrostatic chuck 10 is in the second state, the lifting pin 170 may drive the focus ring 150 in the vertical direction, and may not drive the support ring 140. More specifically, when the electrostatic chuck 10 is in the second state, the focus ring 150 may be spaced apart from the insulation pillar 130 in the vertical direction, and the support ring 140 may come into contact with the insulation pillar 130.

In an embodiment, the second state of the electrostatic chuck 10 may be a state in which the focus ring 150 is driven in the vertical direction to change the shape of the plasma generated in the substrate processing process. In addition, when the electrostatic chuck 10 is in the second state, the substrate S may be placed on the chuck plate 120.

In an embodiment, the lifting pin 170 may be positioned in the second driving groove H3 of the focus ring 150 and may come into contact with the second contact part 151. In addition, the lifting pin 170 may be positioned in the first driving groove H2 of the support ring 140 and may not come into contact with the first contact part 143. However, the present disclosure is not limited thereto, and the lifting pin 170 may be positioned in the first driving groove H2 of the support ring 140 and come into contact with the first contact part 143, but may not drive the support ring 140 in the vertical direction.

In an embodiment, when the lifting pin 170 moves vertically beyond the depth of the second driving groove H3 but within the depth of the first driving groove H2, the lifting pin 170 may drive only the focus ring 150 in the vertical direction. When the focus ring 150 is driven vertically while the support ring 140 is in contact with the insulation pillar 130, the vertical separation distance between the focus ring 150 and the insulation pillar 130 may be smaller than the depth value of the first driving groove H2 of the support ring 140. For example, when the support ring 140 is in contact with the insulation pillar 130, the maximum vertical separation distance between the focus ring 150 and the insulation pillar 130 may be substantially equal to the difference between the depth of the first driving groove H2 and the depth of the second driving groove H3.

FIG. 5 is an enlarged cross-sectional view of the side A of the electrostatic chuck 10 in the third state. The third state of the electrostatic chuck 10 may be a state in which the lifting pin 170 drives the support ring 140 and the focus ring 150 together in the vertical direction.

Referring to FIG. 5, when the electrostatic chuck 10 is in the third state, the lifting pin 170 may drive the support ring 140 and the focus ring 150 together. More specifically, when the electrostatic chuck 10 is in the third state, the support ring 140 and the focus ring 150 may be vertically spaced from the insulation pillar 130.

In an embodiment, the third state of the electrostatic chuck 10 may be a state in which the support ring 140 and the focus ring 150 are driven together in the vertical direction for replacement of at least one ring among the support ring 140 and the focus ring 150. In addition, when the electrostatic chuck 1010 is in the third state, the substrate S may not be seated on the chuck plate 120.

In an embodiment, the lifting pin 170 may be positioned in the first driving groove H2 of the support ring 140 and may come into contact with the first contact part 143. In addition, the lifting pin 170 may be positioned in the second driving groove H3 of the focus ring 150 and may come into contact with the second contact part 151. In the third state of the electrostatic chuck 10, the surface where the first contact part 143 of the support ring 140 comes into contact with the lifting pin 170 may be substantially at the same level as the surface where the second contact part 151 of the focus ring 150 comes into contact with the lifting pin 170.

When the lifting pin 170 moves vertically beyond the depth of the first driving groove H2 of the support ring 140, the lifting pin 170 may drive the support ring 140 and the focus ring 150 together in the vertical direction.

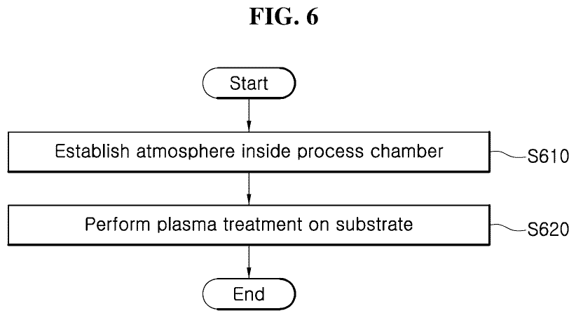

FIG. 6 is a flowchart showing a substrate processing method performed by the substrate processing apparatus 1 according to the present disclosure. The substrate processing apparatus 1 includes: a process chamber 1501 forming a processing space for a substrate S; a chuck plate 120 supporting the substrate S; a focus ring 150 provided on the upper edge of the chuck plate 120; a lifting pin 170 for lifting the focus ring 150; a gas supply part 1520 that supplies process gas to the processing space; a RF power source 1510 that provides RF power to generate plasma in the processing space; and a controller 1550. The substrate processing method described below may be performed by each module of the substrate processing apparatus 1 according to a command signal generated by the controller 1550.

The controller 1550 may include: a control circuit for controlling each driving part of the substrate processing apparatus 1; a processor for performing data processing and calculation for the operation of the substrate processing apparatus 1; a memory for storing data; and a communication module for transmitting and receiving data.

The substrate processing method according to the present disclosure includes: establishing (S610) an atmosphere inside the process chamber 1501; and performing (S620) plasma treatment on the substrate S. In step S610, the controller 1550 executes an operation to establish an internal atmosphere of the process chamber 1501. Establishing an atmosphere inside the process chamber 1501 may be referred to as “aging”. At step S610, internal cleaning and inspection of the process chamber 1501 are executed, and gas to be used for processing is supplied to the process chamber 1501 in advance, or the internal temperature and pressure are controlled. When the internal atmosphere aging is completed, plasma processing for the substrate S is actually executed at step S620.

In the present disclosure, in the step of establishing (S610) an atmosphere inside the process chamber 1501, a process of removing foreign substances established due to a sharp portion formed on the surface of the focus ring 150 is performed. In the present disclosure, a first process gas, which is an aging gas AG, is supplied to the focus ring 150 to change the surface shape of the focus ring 150, and a second process gas, which is a cleaning gas ISD, is supplied to remove foreign substances attached to the focus ring 150.

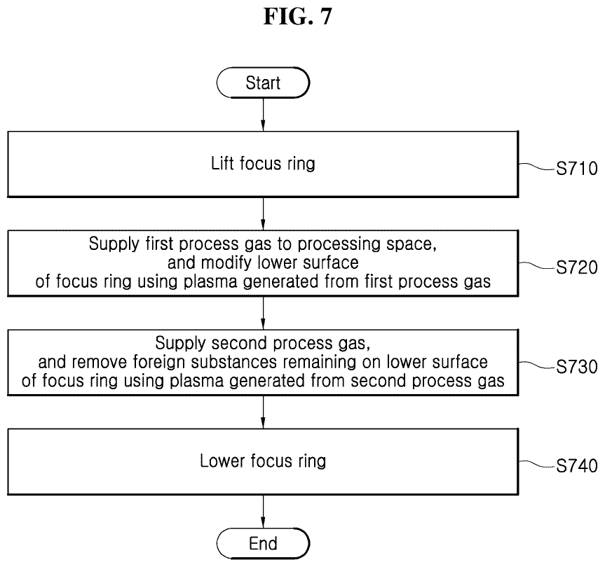

FIG. 7 is a flowchart showing an example of the steps for establishing an atmosphere inside the process chamber 1501. The step (S610) of establishing an atmosphere inside the process chamber 1501 includes: lifting the focus ring 150 (S710); supplying the first process gas to the processing space while the focus ring 150 is lifted, and modifying the surface of the focus ring 150 using the plasma generated from the first process gas (S720); supplying the second process gas while the focus ring 150 is lifted and removing foreign substances remaining on the surface of the focus ring 150 using plasma generated from the second process gas (S730); and lowering the focus ring 150 (S740).

According to the present disclosure, while the focus ring 150 is lifted, the shape of the surface of the focus ring 150, particularly the lower surface, is smoothly modified using the first process gas, which is the aging gas AG. In addition, foreign substances attached to the surface of the focus ring 150, particularly the lower surface, are removed using the second process gas, which is the cleaning gas ISD.

At step S710, the controller 1550 raises the focus ring 150 from the initial position. The controller 1550 raises the lifting pin 170 by means of the ring lifting power source 190, and the focus ring 150 may be raised by the lifting pin 170. As shown in FIG. 4, the lifting pin 170 may press and raise the bottom of the focus ring 150. At this time, the support ring 140 does not rise, and the focus ring 150 may rise from the support ring 140. In another example, as shown in FIG. 5, the support ring 140 and the focus ring 150 may rise together.

At step S720, the controller 1550 supplies the first process gas to the processing space while the focus ring 150 is raised, and modifies the surface of the focus ring 150 using the plasma generated from the first process gas AG. The controller 1550 controls the gas supply part 1520 to supply the first process gas. In addition, the controller 1550 prompts the high-frequency power source 1510 to supply high-frequency power to the upper electrode to generate plasma from the first process gas A G. The first process gas includes at least one of nitrogen trifluoride (NF₃), trifluoromethane (CHF₃), carbon tetrafluoride (CF₄), and nitrogen (N₂). In step S720, the process may be performed while an unprocessed substrate which is a non-patterned wafer (NPW) is mounted on the chuck plate 120. The unprocessed substrate NPW may be a bare wafer on which a pattern is not formed.

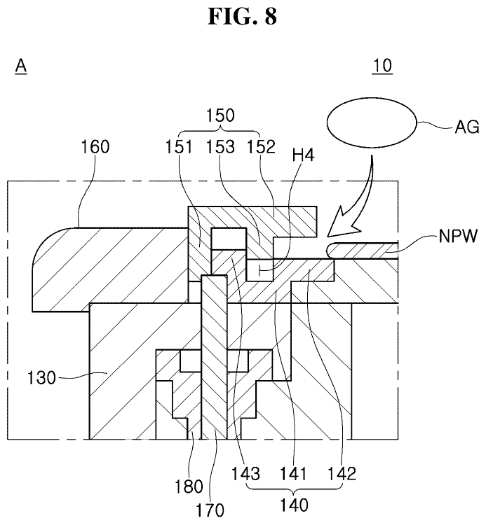

As shown in FIG. 8, the plasma generated from the first process gas, which is the aging gas AG, modifies the shape of the surface of the focus ring 150, particularly the lower surface. In the step of modifying S720 the surface of the focus ring 150, the sharp portion formed on the surface of the focus ring 150 by the plasma is smoothed.

At step S730, the controller 1550 supplies the second process gas while the focus ring 150 is raised, and removes foreign substances remaining on the surface of the focus ring 150 using plasma generated from the second process gas. The step of removing S730 foreign substances remaining on the surface of the focus ring 150 is performed while the unprocessed substrate NPW is removed.

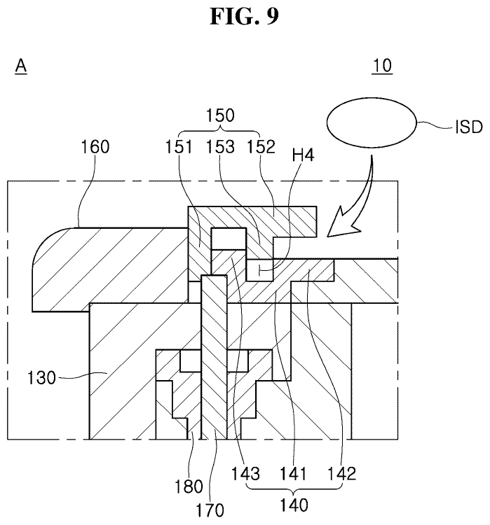

The controller 1550 controls the gas supply part 1520 to supply the second process gas. In addition, the controller 1550 prompts the high-frequency power source 1510 to supply high-frequency power to the upper electrode to generate plasma from the second process gas (AG). The second process gas may include at least one of tetrafluoride (CF₄), oxygen (O), helium (He), and argon (Ar). As illustrated in FIG. 9, foreign substances remaining on the surface of the focus ring 150, particularly on the lower surface of the focus ring 150, may be removed by the second process gas, which is the cleaning gas ISD.

At step S740, the controller 1550 lowers the focus ring 150 and restores the focus ring 150 to the original position thereof. When the focus ring 150 is lowered, the focus ring 150 comes into contact with the upper portion of the support ring 140 as shown in FIG. 3. By cleaning the focus ring 150 with the second process gas together with the surface treatment of the focus ring 150 with the first process gas, it is possible to prevent process defects caused by foreign substances that commonly occur in the initial stage of the focus ring 150.

The substrate processing method described above may be performed by the substrate processing apparatus 1 of FIG. 1. The substrate processing apparatus 1 includes: a process chamber 1501 forming a processing space for a substrate S; a chuck plate 120 supporting the substrate S; an insulation pillar 130 provided at the edge of the chuck plate 120 and having a pin hole H1; a support ring 140 surrounding the side of the chuck plate 120 on the insulation pillar 130; a focus ring 150 covering at least a portion of the upper portion of the support ring 140; a lifting pin 170 configured to be vertically movable in the pin hole H1 of the insulation pillar 130 and vertically overlapped with at least a portion of the support ring 140 and at least a portion of the focus ring 150; a gas supply part 1520 that supplies process gas to the processing space; a high-frequency power source 1510 that provides high-frequency power to generate plasma in the processing space; and a controller 1550.

The controller 1550 is set to execute the step (S610) of establishing an atmosphere inside the process chamber 1501 and the step (S620) of performing plasma treatment on the substrate S. The step (S610) of establishing an atmosphere inside the process chamber 1501 includes: lifting the focus ring 150 (S710); supplying the first process gas to the processing space while the focus ring 150 is lifted, and modifying the surface of the focus ring 150 using the plasma generated from the first process gas (S720); supplying the second process gas while the focus ring 150 is lifted and removing foreign substances remaining on the surface of the focus ring 150 using plasma generated from the second process gas (S730); and lowering the focus ring 150 (S740).

In an embodiment of the present disclosure, the chuck plate 120 includes a first part 121 on which the substrate S is mounted, and a second part 122 extending outwardly from below the first part 121. The support ring 140 includes: a support part 141 that is mounted on the insulation pillar 130; a protective part 142 that extends horizontally from the inside of the support part 141 and surrounds the side surface of the first part 121 and the upper surface of the second part 122 of the chuck plate 120; and a first contact part 143 having a first driving groove H2 extending vertically from the outside of the support part 141 and in which the lifting pin 170 can be positioned.

In an embodiment of the present disclosure, the focus ring 150 includes: a second contact part 151 having a second driving groove H3 that wraps around the support ring 140 on the insulation pillar 130 and in which the lifting pin 170 can be positioned; a cover part 152 extending horizontally from the second contact part 151 and covering at least a portion of the upper portion of the support ring 140; and a protrusion part 153 protruding downward from the cover part 152. The depth of the second driving groove H3 is smaller than the depth of the first driving groove H2, and when the lifting pin 170 is driven vertically beyond the depth of the second driving groove H3 but within the depth of the first driving groove H2, the lifting pin 170 drives the focus ring 150 vertically while the support ring 140 is fixed, whereas when the lifting pin 170 moves vertically beyond the depth of the first driving groove H2, the lifting pin 170 drives the support ring 140 and the focus ring 150 together in the vertical direction.

In an embodiment of the present disclosure, in the step (S720) of modifying the surface of the focus ring 150, a sharp portion formed on the surface of the focus ring 150 be smoothed.

In an embodiment of the present disclosure, the first process gas may include at least one of tetrafluoride (CF₄), oxygen (O₂), helium (He), and argon (Ar).

In an embodiment of the present disclosure, the step (S720) of modifying the surface of the focus ring 150 may be performed while an unprocessed substrate NPW is seated on the chuck plate 120.

In an embodiment of the present disclosure, the step (S730) of removing foreign substances remaining on the surface of the focus ring 150 may be performed in a state where the unprocessed substrate NPW has been removed.

In an embodiment of the present disclosure, second process gas may include at least one of tetrafluoride (CF₄), oxygen (O₂), helium (He), and argon (Ar).

The present embodiments and drawings attached to this specification only clearly illustrate a part of the technical idea included in the present disclosure, and it is obvious that all modifications and specific embodiments that can be easily inferred by those skilled in the art within the scope of the technical idea included in the specification and drawings of the present disclosure are included in the scope of the rights of the present disclosure.

Therefore, the idea of the present disclosure should not be limited to the described embodiments, and not only the patent claims described below, but also all things that are equivalent or have equivalent modifications to these patent claims are considered to fall within the scope of the present disclosure.

What is claimed is:

1. A substrate processing apparatus that performs a processing process using plasma, the apparatus comprising:
a process chamber configured to form a processing space for a substrate;
a chuck plate configured to support the substrate;
a focus ring provided on an upper edge of the chuck plate;
a lifting pin configured to lift the focus ring;
a gas supply part configured to supply process gas to the processing space;
a radio frequency (RF) power source configured to provide RF power to generate plasma in the processing space; and
a controller,
wherein the controller is set to execute steps of:
establishing an atmosphere inside the process chamber; and
performing plasma treatment on the substrate,
wherein the step of establishing the atmosphere inside the process chamber comprises steps of:
lifting the focus ring;
supplying a first process gas to the processing space while the focus ring is lifted, and modifying a surface of the focus ring using plasma generated from the first process gas;
supplying a second process gas while the focus ring is lifted and removing foreign substances remaining on the surface of the focus ring using plasma generated from the second process gas; and
lowering the focus ring.

2. The apparatus of claim 1, wherein in the step of modifying the surface of the focus ring, a sharp portion formed on the surface of the focus ring is smoothed.

3. The apparatus of claim 1, wherein the first process gas includes at least one of nitrogen trifluoride (NF₃), trifluoromethane (CHF₃), carbon tetrafluoride (CF₄), and nitrogen (N₂).

4. The apparatus of claim 1, wherein the step of modifying the surface of the focus ring is performed while an unprocessed substrate is seated on the chuck plate.

5. The apparatus of claim 4, wherein the step of removing foreign substances remaining on the surface of the focus ring is performed with the unprocessed substrate removed.

6. The apparatus of claim 1, wherein the second process gas includes at least one of tetrafluoride (CF₄), oxygen (O₂), helium (He), and argon (Ar).

7. A substrate processing method performed in a substrate processing apparatus that performs a processing process using plasma, the method comprising steps of:
establishing an atmosphere inside a process chamber forming a processing space for a substrate; and
performing plasma treatment on the substrate,
wherein the step of establishing the atmosphere inside the process chamber comprises steps of:
lifting the focus ring located on an upper edge of a chuck plate supporting the substrate;
supplying a first process gas to the processing space while the focus ring is lifted, and modifying a surface of the focus ring using plasma generated from the first process gas;
supplying a second process gas while the focus ring is lifted and removing foreign substances remaining on the surface of the focus ring using plasma generated from the second process gas; and
lowering the focus ring.

8. The method of claim 7, wherein in the step of modifying the surface of the focus ring, a sharp portion formed on the surface of the focus ring is smoothed.

9. The method of claim 7, wherein the first process gas includes at least one of nitrogen trifluoride (NF₃), trifluoromethane (CHF₃), carbon tetrafluoride (CF₄), and nitrogen (N₂).

10. The method of claim 7, wherein the step of modifying the surface of the focus ring is performed while an unprocessed substrate is seated on the chuck plate.

11. The method of claim 10, wherein the step of removing foreign substances remaining on the surface of the focus ring is performed with the unprocessed substrate removed.

12. The method of claim 7, wherein the second process gas includes at least one of tetrafluoride (CF₄), oxygen (O₂), helium (He), and argon (Ar).

13. A substrate processing apparatus that performs a processing process using plasma, the apparatus comprising:
a process chamber configured to form a processing space for a substrate;
a chuck plate configured to support the substrate;
an insulation pillar located at an edge of the chuck plate and configured to have a pin hole formed therein;
a support ring configured to surround a side of the chuck plate on the insulation pillar;
a focus ring configured to cover at least a portion of an upper portion of the support ring;
a lifting pin configured to be movable in a vertical direction in the pin hole of the insulation pillar, and to vertically overlap with at least a portion of the support ring and at least a portion of the focus ring;
a gas supply part configured to supply process gas to the processing space;
a high-frequency power source configured to provide high-frequency power to generate plasma in the processing space; and
a controller,
wherein the controller is set to execute steps of:
establishing an atmosphere inside the process chamber; and
performing plasma treatment on the substrate,
wherein the step of establishing the atmosphere inside the process chamber comprises steps of:
lifting the focus ring;
supplying a first process gas to the processing space while the focus ring is lifted, and modifying a surface of the focus ring using plasma generated from the first process gas;
supplying a second process gas while the focus ring is lifted and removing foreign substances remaining on the surface of the focus ring using plasma generated from the second process gas; and
lowering the focus ring.

14. The apparatus of claim 13, wherein the chuck plate comprises:
a first part on which the substrate is seated; and
a second part extending outwardly from below the first part, and
the support ring comprises:
a support part seated on the insulation pillar;
a protective part configured to extend horizontally from an inside of the support part and wrap around a side of the first part and an upper surface of the second part of the chuck plate; and
a first contact part configured to extend vertically from an outside of the support part and have a first driving groove in which the lifting pin is positioned.

15. The apparatus of claim 14, wherein the focus ring comprises:
a second contact part configured to surround the support ring on the insulation pillar and have a second driving groove in which the lifting pin is positioned;
a cover part configured to extend horizontally from the second contact part and cover at least a portion of an upper portion of the support ring; and
a protrusion part protruding downward from the cover part,
wherein a depth of the second driving groove is smaller than a depth of the first driving groove, and
when the lifting pin moves in the vertical direction beyond the depth of the second driving groove but within the depth of the first driving groove, the lifting pin drives the focus ring in the vertical direction with the support ring fixed, whereas
when the lifting pin moves in the vertical direction beyond the depth of the first driving groove, the lifting pin drives the support ring and the focus ring together in the vertical direction.

16. The apparatus of claim 13, wherein in the step of modifying the surface of the focus ring, a sharp portion formed on the surface of the focus ring is smoothed.

17. The apparatus of claim 13, wherein the first process gas includes at least one of nitrogen trifluoride (NF₃), trifluoromethane (CHF₃), carbon tetrafluoride (CF₄), and nitrogen (N₂).

18. The apparatus of claim 13, wherein the step of modifying the surface of the focus ring is performed while an unprocessed substrate is seated on the chuck plate.

19. The apparatus of claim 18, wherein the step of removing foreign substances remaining on the surface of the focus ring is performed with the unprocessed substrate removed.

20. The apparatus of claim 13, wherein the second process gas includes at least one of tetrafluoride (CF₄), oxygen (O₂), helium (He), and argon (Ar).
